(19) United States
(12) Patent Application Publication
(10) Pub. No.: US 2015/0158981 A1
(43) Pub. Date: Jun. 11, 2015

(54) CURABLE COMPOSITION AND AN OPTICAL SEMICONDUCTOR DEVICE

(71) Applicant: SHIN-ETSU CHEMICAL CO., LTD., Tokyo (JP)

(72) Inventors: Takayuki KUSUNOKI, Annaka-shi (JP); Yuusuke TAKAMIZAWA, Annaka-shi (JP); Tsutomu KASHIWAGI, Annaka-shi (JP)

(21) Appl. No.: 14/560,236

(22) Filed: Dec. 4, 2014

(30) Foreign Application Priority Data
Dec. 6, 2013 (JP) 2013-253652

(51) Int. Cl. C08G 77/04; H01L 33/56

(52) U.S. Cl. CPC C08G 77/04; H01L 33/56; C08G 2190/00

(57) ABSTRACT

A curable composition includes (A) an isocyanurate represented by the formula (1), (B) a combination of (B-1) a non-cyclic organopolysiloxane which may have a branched structure, has hydrogen atoms each bonded to a silicon atom at at least two terminals, and monovalent aromatic hydrocarbon groups each bonded to a silicon atom in an amount of 10% or more and (B-2) a non-cyclic organopolysiloxane which may have a branched structure, has at least two hydrogen atoms each bonded to a silicon atom in a main and/or branched chains, but no SiH group at any terminal, and has a monovalent aromatic hydrocarbon group bonded to a silicon atom in an amount of 10% or more, and (C) a hydrosilylation catalyst in a catalytic amount.

### CROSS REFERENCE

This application claims the benefits of Japanese Patent Application No. 2013-253652 filed on Dec. 6, 2013, the contents of which are herein incorporated by reference.

### FIELD OF THE INVENTION

The present invention relates to a curable composition and an optical semiconductor device. Specifically, the present invention relates to an encapsulating material for light-emitting diodes (LEDs) and further relates to an encapsulating material which provides a cured product having a high optical transparency, high strength and high crack resistance, and a light-emitting diode encapsulated with the material.

In recent years, an acid anhydride-type of curable transparent epoxy resins which have a high gas barrier property and an excellent mechanical strength have been widely used as encapsulating materials for LEDs. The epoxy resins are organic polymers, so that they have disadvantages such as low resistance to high heat and powerful light generated by LEDs. Therefore, silicone resins have been widely used as a material to solve these problems. However, the silicone resins have problems such that the mechanical strength is poor and a gas barrier property is too low to sufficiently protect metal lines such as gold lines and silver lines present on an LED substrate from an ambient corrosive gas.

In order to solve the aforesaid problems, hybrid silicone resins, such as silicone resins modified with organic compounds, are developed. However, compatibility between the silicone resin and the organic component is bad and, therefore, cured product obtained has poor transparency. Further, heat resistance, light resistance, mechanical strength and a gas barrier property of the cured product are not sufficient.

Japanese Patent Application Laid-Open No. 2004-131518, Patent Literature 1, describes a curable composition comprising a reaction product of a compound having an isocyanuric acid structure with a siloxane compound having SiH groups at the both terminals and a compound having an isocyanuric acid structure, and states that the composition is homogeneous and has an excellent curing property. Japanese. Patent Application Laid-Open No. 2004-131519, Patent Literature 2, describes a curable composition comprising a siloxane compound having SiH groups on a main chain, but no SiH group at any terminal, and triallylisocyanurate, and states that a cured product obtained from the composition has high optical transparency.

Further, Japanese Patent Application Laid-Open No. 2010-275365, Patent Literature 3, describes a curable composition which comprises a reaction product of (B1) an organic compound which has an isocyanuric acid structure and at least two carbon-carbon double bonds reactive with an SiH group in a molecular with (B2) a cyclic siloxane compound which has at least two SiH groups in a molecular, a reaction product of (C1) an organic compound which has an isocyanuric acid structure and at least one carbon-carbon double bond reactive with an SiH group in a molecular with (C2) a cyclic siloxane compound which has at least two SiH groups in a molecular, and a hydrosilylation catalyst. Patent Literature 3 describes that a cured product obtained from the composition has good heat resistance and small shrinkage on curing.

### PRIOR LITERATURES

### Patent Literatures

[Patent Literature 1] Japanese Patent Application Laid-Open No. 2004-131518

[Patent Literature 2] Japanese Patent Application Laid-Open No. 2004-131519

[Patent Literature 3] Japanese Patent Application Laid-Open No. 2010-275365

### DISCLOSURE OF THE INVENTION

### Problems to be Solved by the Invention

However, for the preparation of the compositions described in Patent Literatures 1 and 3, the organic compound having an isocyanuric acid structure is reacted with the siloxane compound in advance, which is disadvantageous in costs. Further, in the composition described in Patent Literature 1, the siloxane compound has SiH groups at only terminals and, therefore, a cured product obtained has a low hardness and a poor gas barrier property. The compositions described in Patent Literatures 2 and 3 have a problem of low crack resistance in heat cycles and, therefore, are not sufficient as an encapsulating material for LEDs which are used in various environments.

One of the purposes of the present invention is to provide a curable composition which comprises an organic compound having an isocyanuric acid structure and a silicone compound, can be prepared in a simple process and provides a cured product having an excellent gas barrier property, excellent crack resistance, and a high optical transparency. Further, another purpose is to provide an optical semiconductor device provided with a cured product obtained by curing the curable composition.

### Means to Solve the Problems

To solve the aforesaid problems, the present inventors have made research and found that a composition comprising a silicone compound having at least two SiH groups at the terminals in combination with a silicone compound having at least two SiH groups on a main and/or branched chains, but no SiH group at any terminal, provides a cured product having an excellent gas barrier property such as low water vapor permeability and excellent crack resistance. Further, the present inventors have found that an organopolysiloxane having a specific amount of monovalent aromatic hydrocarbon groups is well compatible with an organic compound having an isocyanuric acid structure and, therefore, a composition and a cured product have a high transparency.

Thus, the present invention is to provide a curable composition comprising
(A) an isocyanurate represented by the following formula (1):

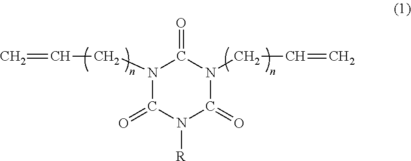

wherein n is, independently of each other, an integer of from 1 to 10, R is selected from the group consisting of monovalent hydrocarbon groups which have 1 to 12 carbon atoms and may have an aliphatic or aromatic unsaturated double bond, an epoxy group and a (meth)acryl group,
(B) a combination of the following components (B-1) and (B-2) in an amount such that a ratio of the number of —SiH groups in component (B) to a total number of the aliphatic unsaturated double bond in component (A) is 0.5 to 4:
   (B-1) a non-cyclic organopolysiloxane which may have a branched structure, has hydrogen atoms each bonded to a silicon atom, i.e. —SiH group, at at least two terminals, and has monovalent aromatic hydrocarbon groups each bonded to a silicon atom in an amount of 10% or more, relative to a total number of substituents and hydrogen atoms each bonded to a silicon atom; and
   (B-2) a non-cyclic organopolysiloxane which may have a branched structure, has at least two hydrogen atoms each bonded to a silicon atom in a main and/or branched chains, i.e. —SiH group, but no SiH group at any terminal, and has a monovalent aromatic hydrocarbon group bonded to a silicon atom in an amount of 10% or more, relative to a total number of substituents and hydrogen atoms each bonded to a silicon atom,
   wherein an amount of component (8-2) is 1 to 99 mass %, relative to a total amount of components (B-1) and (B-2); and
(C) a hydrosilylation catalyst in a catalytic amount.

### Effects of the Invention

The present composition provides a cured product having an excellent mechanical strength, a gas barrier property such as low water vapor permeability, and excellent crack resistance. Additionally, the present curable composition has a high optical transparency before cured, so that a cured product obtained has a high optical transparency. Further, the present composition is prepared in a simple process and, therefore, has an advantage in costs. Accordingly, the present curable composition is useful as an encapsulating material for optical semiconductor devices, in particular an encapsulating material for protecting LED chips and metal lines.

### BEST MODE OF THE INVENTION

The present invention will be described below in detail.

### (A) Isocyanurate

Component (A) is an isocyanurate represented by the following formula (1):

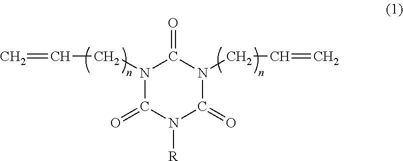

wherein n is, independently of each other, an integer of from 1 to 10, preferably 1 to 6, further preferably 1 to 3, R is selected from the group consisting of monovalent hydrocarbon groups which have 1 to 12 carbon atoms and may have an aliphatic or aromatic unsaturated double bond, an epoxy group and a (meth)acryl group.

Examples of R include alkyl groups such as methyl, ethyl, propyl, isopropyl, octyl and decyl groups; a cyclohexyl group; aryl groups such as phenyl and tolyl groups; alkenyl groups such as vinyl and allyl groups; an ethynyl group; epoxy groups such as a glycidyl group and a 3,4-epoxycyclohexyl group; an acryl group and a methacryl group. Among these, monovalent hydrocarbon groups having 1 to 3 carbon atoms are preferred in view of a gas barrier property and heat resistance. In particular, a methyl group, an ethyl group, a propyl group, an isopropyl group, a vinyl group, and an allyl group are preferred.

In particular, the following compounds are preferred.

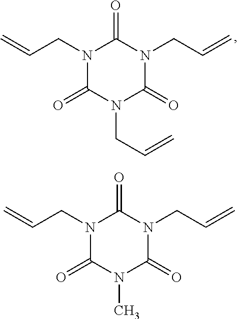

### (B) Organopolysiloxane

Component (B) is a combination of (B-1) a non-cyclic organopolysiloxane which may have a branched structure and has hydrogen atoms each bonded to a silicon atom, hereinafter referred to as SiH group, at at least two terminals and (B-2) a non-cyclic organopolysiloxane which may have a branched structure and has at least two hydrogen atoms each bonded to a silicon atom in a main and/or branched chains, but no SiH group at any terminal. The components are explained below in detail.

Component (B-1) is a non-cyclic organopolysiloxane which may have a branched structure, has SiH groups at at least two terminals, and has monovalent aromatic hydrocarbon groups each bonded to a silicon atom in an amount of 10% or more, relative to a total number of substituents and hydrogen atoms each bonded to a silicon atom. Component (B-1) has SiH groups at at least two terminals, where “terminal” means a terminal of a main chain or a terminal of a branched chain. Preferably, component (B-1) has each one SiH group at each of the both terminals of the main chain. Component (B-1) may have hydrogen atoms each bonded to a silicon atom in the main and/or branched chain. The oraganopolysiloxane may be used singly or in combination of two or more of them. Particularly, component (B-1) is the organopolysiloxane having SiH groups at only terminals.

The number of the monovalent aromatic hydrocarbon groups each bonded to a silicon atom is preferably 10 to 80%, more preferably 15 to 70%, further preferably 20 to 60%, relative to a total number of the substituents and hydrogen atoms each bonded to a silicone atom. If the number is less than the aforesaid lower limit, the organopolysiloxane is not well compatible with the isocyanurate and phase separation occurs, so that a cured product is not obtained. If the number is larger than the aforesaid upper limit, the organopolysiloxane is almost solid and, therefore, tends to be difficult to handle.

Component (B-1) is preferably represented by the following formula (2):

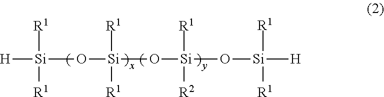

wherein R¹ is, independently of each other, an unsubstituted or substituted, monovalent hydrocarbon group which has 1 to 12 carbon atoms and has no aliphatic unsaturated bond, R² is, independently of each other, selected from the aforementioned groups defined for R¹ or a group represented by the following formula (3):

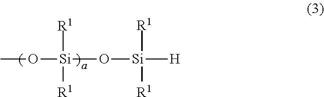

wherein 10% or more of a total number of the substituents and the hydrogen atoms each bonded to a silicon atom is a monovalent aromatic hydrocarbon group, and the parenthesized siloxane units may form a block unit or bond randomly.

In the formula (2), the number of the monovalent aromatic hydrocarbon groups each bonded to a silicon atom is 10% or more, preferably 10 to 80%, more preferably 15 to 70%, further preferably 20 to 60%, relative to a total number of the substituents and hydrogen atoms each bonded to a silicone atom.

In the formula (2), x is an integer of from 0 to 100, y is an integer of from 0 to 100, a is an integer of from 0 to 100, and a total of x, y and a is 1 to 300. Preferably, x is an integer of from 0 to 50, y is an integer of from 0 to 50, a is an integer of from 0 to 50, and a total of x, y and a is 2 to 100.

In the formula (2), R¹ is, independently of each other, a unsubstituted or substituted, monovalent hydrocarbon group which has 1 to 12 carbon atoms, preferably 1 to 10 carbon atoms and has no aliphatic unsaturated bond. Examples of R¹ include alkyl groups such as methyl, ethyl, propyl, butyl and octyl groups; aryl groups such as phenyl, tolyl and naphthyl groups; aralkyl groups such as benzyl, phenylethyl and phenylpropyl groups; and those groups where a part or the whole of their hydrogen atoms are replaced with a halogen atom(s), such as fluorine, bromine and chlorine atoms, or a cyano group, i.e. halogen-substituted monovalent hydrocarbon groups, for instance, a trifluoropropyl and chloropropyl groups. Among these, a methyl group and a phenyl group are preferred. In the formula (2), at least one of R¹ is an aromatic hydrocarbon group, preferably a phenyl group.

Examples of the organopolysiloxane represented by the formula (2) include the following compounds:

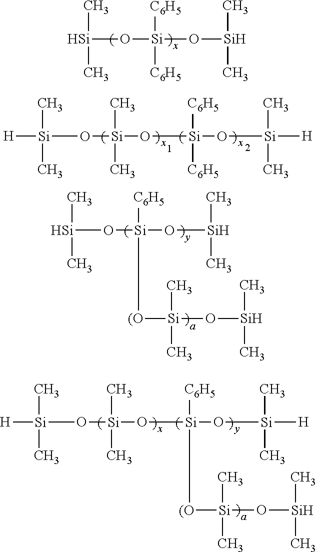

wherein x, y and a are as defined above and x₁ and x₂ are, independently of each other, a positive integer which satisfies the equation x₁+x₂=x.

Component (B-2) is a non-cyclic organopolysiloxane which may have a branched structure, has at least two SiH groups on a main and/or branched chains, but no SiH group at any terminal, and has monovalent aromatic hydrocarbon groups each bonded to a silicon atom in an amount of 10% or more, relative to a total number of substituents and hydrogen atoms each bonded to a silicon atom. The organopolysiloxane may be used singly or in combination of two or more of them.

The number of the monovalent aromatic hydrocarbon groups each bonded to a silicon atom is preferably 10 to 80%, more preferably 15 to 70%, further preferably 20 to 60%, relative to a total number of the substituents and hydrogen atoms each bonded to a silicone atom. If the number is less than the aforesaid lower limit, the organopolysiloxane is not well compatible with the isocyanurate and phase separation occurs, so that a cured product is not obtained. If the number is larger than the aforesaid upper limit, the organopolysiloxane is almost solid and, therefore, tends to be difficult to handle.

Component (B-2) is preferably represented by the following formula (4):

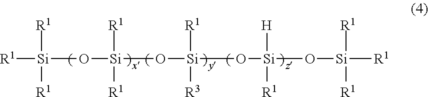

wherein R¹ is, independently of each other, an unsubstituted or substituted, monovalent hydrocarbon group which has 1 to 12 carbon atoms and has no aliphatic unsaturated bond, R³ is a group represented by the following formula (5):

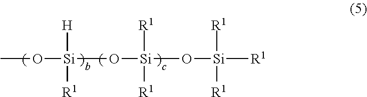

wherein 10% or more of a total number of the substituents and the hydrogen atoms each bonded to a silicon atom is a monovalent aromatic hydrocarbon group, and the parenthesized siloxane units may form a block unit or bond randomly.

In the formula (4), the number of the monovalent aromatic hydrocarbon groups each bonded to a silicon atom is 10% or more, preferably 10 to 80%, more preferably 15 to 70%, further preferably 20 to 60%, relative to a total number of the substituents and hydrogen atoms each bonded to a silicone atom.

In the formula (4), x′ is an integer of from 0 to 300, y′ is an integer of from 0 to 300, z′ is an integer of from 0 to 300, b is an integer of from 0 to 300, c is an integer of from 0 to 300, and a total of x′, y′, z′, b and c is 2 to 500. Preferably, x′ is an integer of from 0 to 100, y′ is an integer of from 0 to 100, z′ is an integer of from 2 to 100, b is an integer of from 1 to 100, c is an integer of from 0 to 100, and a total of x′, y′, z′, b and c is 2 to 300. A total of z′ and b is 2 or more.

In the formula (4), R¹ is, independently of each other, an unsubstituted or substituted, monovalent hydrocarbon group which has 1 to 12 carbon atoms, preferably 1 to 10 carbon atoms and has no aliphatic unsaturated bond. Examples of R¹ include alkyl groups such as methyl, ethyl, propyl, butyl and octyl groups; aryl groups such as phenyl, tolyl and naphthyl groups; aralkyl groups such as benzyl, phenylethyl and phenylpropyl groups; and those groups where a part or the whole of their hydrogen atoms are replaced with a halogen atom(s), such as fluorine, bromine and chlorine atom, or a cyano group, i.e. halogen-substituted monovalent hydrocarbon groups, for instance, a trifluoropropyl and chloropropyl groups. Among these, a methyl group and a phenyl group are preferred. In the formula (4), at least one of R¹ is an aromatic hydrocarbon group, preferably a phenyl group.

Examples of the organopolysiloxane represented by the formula (4) include the following compounds:

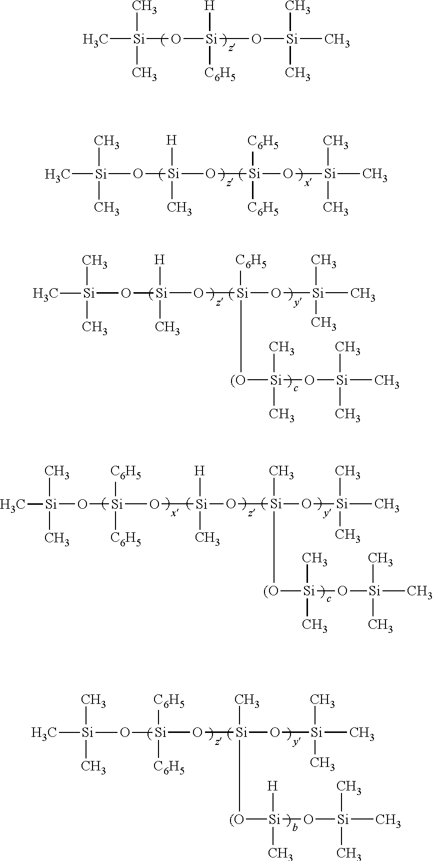

wherein x′, y′, z′, b and c are as defined above.

A mass ratio of component (B-1) to component (B-2) in component (B) is such that an amount of component (B-2) is 1 to 99 mass %, preferably 5 to 95 mass %, further preferably 10 to 90 mass %, relative to a total amount of components (B-1) and (B-2).

The present component (B) may further comprise, in addition to components (B-1) and (B-2), (B-3) a non-cyclic organopolysiloxane which may have a branched structure, has hydrogen atoms each bonded to a silicon atom in a main and/or branched chains and at one terminal, i.e. SiH group, and has monovalent aromatic hydrocarbon groups each bonded to a silicon atom in an amount of 10% or more, relative to a total number of substituents and hydrogen atoms each bonded to a silicon atom.

The number of the monovalent aromatic hydrocarbon groups each bonded to a silicon atom is preferably 10 to 80%, more preferably 15 to 70%, further preferably 20 to 60%, relative to a total number of the substituents and hydrogen atoms each bonded to a silicone atom. If the number is less than the aforesaid lower limit, the organopolysiloxane is not well compatible with the isocyanurate and phase separation occurs, so that a cured product is not obtained. If the number is larger than the aforesaid upper limit, the organopolysiloxane is almost solid and, therefore tends to be difficult to handle.

Component (B-3) is preferably represented by the following formula (6):

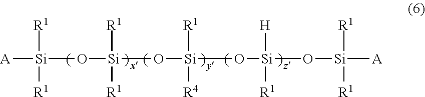

wherein R¹ is as defined above, R⁴ is a group represented by the following formula (7):

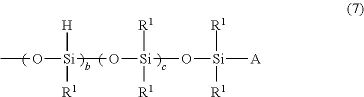

wherein A is a hydrogen atom or a group represented by R¹ and at least one of A is a hydrogen atom. The parenthesized siloxane units may form a block unit or bond randomly. x′ is an integer of from 0 to 300, y′ is an integer of from 0 to 300, z′ is an integer of from 0 to 300, b is an integer of from 0 to 300, c is an integer of from 0 to 300, and a total of x′, y′, z′, b and c is 2 to 500. Preferably, x′ is an integer of from 0 to 100, y′ is an integer of from 0 to 100, z′ is an integer of from 1 to 100, b is an integer of from 1 to 100, c is an integer of from 0 to 100, and a total of x′, y′, z′, b and c is 2 to 300. z′ and b are not zero at the same time.

An amount of component (B-3) in component (B) is preferably 1 to 50 mass %, more preferably 5 to 40 mass %, further preferably 10 to 30 mass %, relative to a total mass of component (B).

An amount of component (B) in the curable composition is such that a ratio of the number of the SiH groups in component (B) to a total number of the aliphatic unsaturated double bonds in component (A) is 0.5 to 4, preferably 0.8 to 2.

### (C) Hydrosilylation Catalyst

Component (C) is a hydrosilylation catalyst. Any catalyst may be used as long as it accelerates the hydrosilylation of components (A) and (B). In particular, a catalyst selected from a platinum group metal and a platinum group metal compound is preferable. Examples of the catalyst include platinum catalysts such as platinum including platinum black, platinum chloride, chloroplatinate, a complex of platinum and an olefin, such as a complex of platinum and divinylsiloxane, and a complex of platinum and carbonyl; palladium catalysts and rhodium catalysts. The afore-mentioned catalysts may be used singly or in combination of two or more of them. Among these, particularly preferred are chloroplatinate and a complex of platinum and an olefin, such as a complex of platinum and divinylsiloxane.

The catalyst may be used in a catalytic amount. The catalyst amount is such that the hydrosilylation of components (A) and (B) is accelerated and may be properly decided depending on a desired curing rate. For instance, when a platinum group metal catalyst is used, the amount, reduced as a platinum group metal, is preferably 1.0×10⁻⁴ to 1.0 part by mass, more preferably 1.0×10⁻³ to 1.0×10⁻¹ part by mass relative to the total 100 parts by mass of components (A) and (B), in view of reactivity.

The organopolysiloxane (B) is well compatible with the isocyanurate (A). Accordingly, the composition is a highly transparent liquid before cured. In particular, a refractive index of the composition at 589 nm, as determined according to the Japanese Industrial Standards (JIS) K 0062, is 1.45 to 1.6, preferably 1.46 to 1.58, further preferably 1.47 to 1.57. Because the present curable composition is a transparent liquid before cured, it provides a cured product having a high optical transparency.

The present curable composition may further comprises a fluorescent material, an inorganic filler, an adhesion-imparting agent, a liquid silicone besides component (B) and a cure inhibitor in addition to components (A) to (C), if needed. The each component will be explained below in detail.

### Fluorescent Material

Any conventional fluorescent material may be used and not limited to any particular one. For instance, preferred is a fluorescent material which absorbs light generated by a semiconductor light-emitting diode having, as a light emitting layer, a semiconductor element, in particular a nitride semiconductor element and converts its wavelength to different one. The fluorescent material is, for instance, preferably one or more selected from the group consisting of nitride fluorescent materials and oxynitride fluorescent materials which are activated mainly by lanthanide elements such as Eu and Ce; fluorescent materials activated mainly by lanthanide elements such as Eu or transition metal elements such as Mn, such as alkaline earth metal halogen apatites, alkaline earth metal halogen borates, alkaline earth metal aluminates, alkaline earth metal silicates, alkaline earth metal sulfides, alkaline earth metal thiogallates, alkaline earth metal silicon nitrides and germinates; rare earth metal aluminates and rare earth metal silicates which are activated mainly by lanthanide elements such as Ce; organic fluorescent materials and organic complex fluorescent materials which are activated mainly by lanthanide elements such as Eu, and Ca—Al—Si—O—N type oxynitride glass fluorescent materials.

Examples of the nitride fluorescent material which is activated mainly by lanthanide elements such as Eu and Ce include M₂Si₅N₈:Eu, MSi₇N₁₀:Eu, M_{1.8}Si₅O_{0.2}N₈:Eu and M_{0.9}Si₇O_{0.1}N₁₀:Eu, wherein M is at least one selected from the group consisting of Sr, Ca, Ba, Mg and Zn.

Examples of the oxynitride fluorescent material which is activated mainly by lanthanide elements such as Eu and Ce include MSi₂O₂N₂:Eu, wherein M is at least one selected from the group consisting of Sr, Ca, Ba, Mg and Zn.

Examples of the alkaline earth metal halogen apatite fluorescent material which is activated mainly by lanthanide elements such as Eu or transition metal elements such as Mn include M₅(PO₄)₃X:R, wherein M is at least one selected from the group consisting of Sr, Ca, Ba, Mg and Zn, X is at least one selected from the group consisting of F, Cl, Br and I, and R is Eu, Mn, or at least one of Eu and Mn.

Examples of the alkaline earth metal halogen borate fluorescent material include M₂B₅O₉X:R, wherein M is at least one selected from the group consisting of Sr, Ca, Ba, Mg and Zn, X is at least one selected from the group consisting of F, Cl, Br and I, and R is Eu, Mn, or at least one of Eu and Mn.

Examples of the alkaline earth metal aluminate fluorescent material include SrAl₂O₄:R, Sr₄Al₁₄O₂₅:R, CaAl₂O₄:R, BaMg₂Al₁₆O₂₇:R, BaMg₂Al₁₆O₁₂:R and BaMgAl₁₀O₁₇:R, wherein R is Eu, Mn, or at least one of Eu and Mn.

Examples of the alkaline earth metal sulfide fluorescent material include La₂O₂S:Eu, Y₂O₂S:Eu and Gd₂O₂S:Eu.

Examples of the rare earth metal aluminate fluorescent material which is activated mainly by lanthanide elements such as Ce include YAG type fluorescent materials represented by compositional formulas: Y₃Al₅O₁₂:Ce, (Y_{0.8}Gd_{0.2})₃Al₅O₁₂:Ce, Y₃(Al_{0.8}Ga_{0.2})₅O₁₂:Ce, and (Y,Gd)₃(Al,Ga)₅O₁₂ and those compounds where a part or the whole of Y are replaced with Tb or Lu, such as Tb₃Al₅O₁₂:Ce and Lu₃Al₅O₁₂:Ce.

Examples of the other fluorescent materials include ZnS:Eu, Zn₂GeO₄:Mn and MGa₂S₄:Eu, wherein M is at least one selected from the group consisting of Sr, Ca, Ba, Mg and Zn, and X is at least one selected from the group consisting of F, Cl, Br and I.

The afore-mentioned fluorescent materials may comprise at least one selected from the group consisting of Tb, Cu, Ag, Au, Cr, Nd, Dy, Co, Ni and Ti, in place of Eu or in addition to Eu, if needed.

The Ca—Al—Si—O—N type oxynitride glass fluorescent material comprises, as a matrix, oxynitride glass comprising 20 to 50 mole % of CaCO₃, calculated as CaO, 0 to 30 mole % of Al₂O₃, 25 to 60 mole % of SiO, 5 to 50 mole % of AlN and 0.1 to 20 mole % of rare earth metal oxides or transition metal oxides, wherein the total amount of the aforesaid components is 100 mole %. The fluorescent material with the oxynitride glass matrix preferably comprises nitrogen atoms in an amount of 15 weight % or less and preferably comprises the other rare earth metal ion besides rare earth metal oxides ions which work as a sensitizer in an amount of 0.1 to 10 mole %, calculated as rare earth metal oxides, in a fluorescent glass as a co-activator.

Other fluorescent materials besides the aforesaid fluorescent materials, which have the similar functions and provides the similar effects, may be used.

An amount of the fluorescent material is preferably 0.1 to 2,000 parts by mass, more preferably 0.1 to 100 parts by mass, relative to 100 parts by mass of the components other than the fluorescent material, for instance, 100 parts by mass of components (A) to (C). When the present cured product is used as a wavelength conversion film comprising a fluorescent material, the amount of the fluorescent material is preferably 10 to 2,000 parts by mass. Further, the fluorescent material preferably has a mean diameter of 10 nm or more, more preferably 10 nm to 10 μm, further preferably 10 nm to 1 μm. The mean diameter is determined from particle size distribution determined in a laser diffraction method using a Cilas laser measurement instrument.

### Inorganic Filler

Examples of the inorganic filler include inorganic reinforcing fillers such as fumed silica and fumed titanium dioxide, and inorganic non-reinforcing fillers such as calcium carbonate, calcium silicate, titanium dioxide, iron (III) oxide and zinc oxide. These inorganic fillers may be used singly or in combination of two or more of them. An amount of the inorganic filler may be 20 parts by mass or less, preferably 0.1 to 10 parts by mass, relative to the total 100 parts by mass of components (A) and (B), but not limited to these.

### Adhesion-Imparting Agent

The present curable composition may comprise an adhesion-imparting agent in order to add adhesiveness to a cured product, if needed. Examples of the adhesion-imparting agent include linear or cyclic organosiloxane oligomers having at least two, preferably three, functional groups selected from the group consisting of a hydrogen atom bonded to a silicon atom, an alkenyl group, an alkoxy group and an epoxy group. The organosiloxane oligomer preferably has 4 to 50 silicon atoms, preferably has 4 to 20 silicon atoms. Further, the adhesion-imparting agent may be an organooxysilyl-modified isocyanurate represented by the following general formula (8) or a hydrolysis and condensation product of the compound, i.e. organosiloxane-modified isocyanurate.

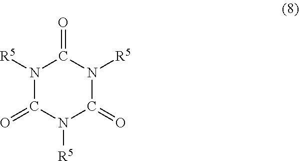

wherein R⁵ is, independently of each other, an organic group represented by the following formula (9) or a monovalent hydrocarbon group having an aliphatic unsaturated bond, provided that at least one of R⁵ is the group represented by the formula (9).

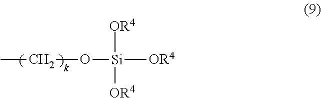

wherein R⁴ is a hydrogen atom or a monovalent hydrocarbon group having 1 to 6 carbon atoms and k is an integer of from 1 to 6, preferably 1 to 4.

An amount of the adhesion-imparting agent is 10 parts by mass or less, preferably 0.1 to 8 parts by mass, more preferably 0.2 to 5 parts by mass, relative to the total 100 parts by mass of components (A) and (B). When the amount of the adhesion-imparting agent is in the aforesaid range, high hardness of the cured product is attained and surface tackiness of the cured product is avoided.

### Liquid Silicone

The present curable composition may contain a liquid silicone besides component (B), if needed. The liquid silicone preferably has a viscosity at 25 degrees C. of about 1 to 100,000 mPa·s. For instance, use may be made of vinylsiloxanes, hydrogensiloxanes, alkoxysiloxanes, hydroxysiloxanes and a mixture of them. An amount of the liquid silicone is preferably 50 mass % or less, relative to a total amount of the curable composition.

### Cure Inhibitor

The present curable composition may comprise a cure inhibitor in order to control reactivity to improve storage stability. Examples of the cure inhibitor include triallylisocyanurate, alkyl maleate, acetylene alcohols, silane-modified or siloxane-modified product of these, hydroperoxide, tetramethylethylenediamine, benzotriazole and a mixture of them. An amount of the cure inhibitor is preferably 0.001 to 1.0 part by mass, further preferably 0.005 to 0.5 part by mass, relative to the total 100 parts by mass of components (A) and (B).

### Other Additives

The present curable composition may comprise other additives besides the aforesaid components. Examples of the other additives include anti-aging agents, radical polymerization inhibitors, flame retardants, surfactants, antiozonants, light stabilizers, thickeners, plasticizers, antioxidants, heat stabilizers, electrical conductivity-imparting agents, antistatic agents, radiation insulating agents, nucleating agents, phosphoric-type peroxide decomposers, lubricants, pigments, metal-inactivating agents, physical property-adjusting agents and organic solvents. These optional components may be used single or in combination of two or more of them.

The simplest embodiment of the present curable composition consists of components (A), (B) and (C). Preferably, the composition consists of components (A), (B) and (C) and the fluorescent material. In particular, it is preferred that the composition does not comprise any inorganic filler such as silica, in order to provide a cured product having a higher transparency. The inorganic filler is as described above.

The present curable composition may be prepared in any known manners which are not limited to any particular one. For instance, the composition may be prepared by mixing components (A), (B) and (C) in any manners. Further, the present composition may be prepared by mixing components (A), (B) and (C) and the fluorescent material or mixing components (A), (B) and (C) and the optional components in any manners. For instance, the aforesaid components are put in a commercial stirrer, such as THINKY CONDITIONING MIXER, ex Thinky Corporation, and mixed homogeneously for about 1 to 5 minutes to prepare the present curable composition.

The present curable composition may be cured in any known manners and curing conditions are not limited to any particular ones. For instance, the composition may be maintained at 60 to 180 degrees C. for 1 to 12 hours. In particular, the composition is preferably cured step-wise in the range of 60 to 180 degrees C., where the curable composition is first heated at 60 to 100 degrees C. for 0.5 to 2 hours to be defoamed sufficiently and, subsequently, the composition is heated at 120 to 180 degrees C. for 1 to 10 hours to be cured. According to these steps, the composition is cured sufficiently, no bubble occur and the cured product is colorless and transparent even when a cured product has a large thickness. In the present invention, the colorless and transparent cured product means that a light transmittance at 450 nm of the cured product having a thickness of 1 mm is 80% or more, preferably 85% or more, particularly preferably 90% or more.

The curable composition provides a cured product having a high optical transparency. Accordingly, the present curable composition is useful as an encapsulating material for LED elements, in particular blue LED elements and violet LED elements. The encapsulation of LED elements with the present curable composition may be carried out in any known manners. For instance, a dispense method and a compression molding method may be used.

On account of the excellent heat resistance, high light resistance and high transparency, the present curable composition and cured product are also useful as materials for displays, optical recording mediums, optical apparatus, optical components and optical fibers, and photo/electron functional organic materials and materials for peripheral elements of integrated semiconductor circuits.

### EXAMPLES

The present invention will be explained below in further detail with reference to a series of the Examples and the Comparative Examples, though the present invention is in no way limited by these Examples. In the following descriptions, an amount of an aromatic group is a percentage of the number of monovalent aromatic hydrocarbon groups each bonded to a silicon atom, relative to a total number of substituents and hydrogen atoms each bonded to a silicon atom.

Mixed were 21.5 g of 1,3,5-triallylisocyanurate represented by the following formula (10), TAIC, ex Nissan Chemical Industries, Ltd., 52.4 g of a silicone compound having SiH groups at the both terminals, which was represented by the following formula (11), ex Shin-Etsu Chemical Co., Ltd., and 26.2 g of a silicone compound having SiH groups on a main, but no SiH group at any terminal, which was represented by the following formula (12). To the mixture, added was a complex of chloroplatinic acid and divinylsiloxane in an amount of 5 ppm of platinum, and mixed to prepare a curable composition.

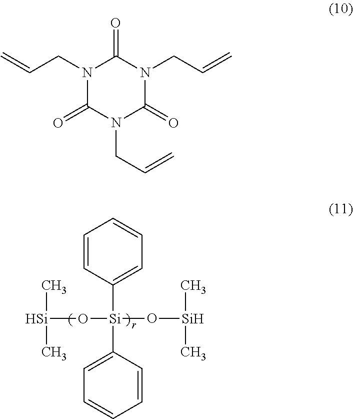

wherein r is 1 to 3, an average of r is 2 and an amount of the aromatic groups is 40%.

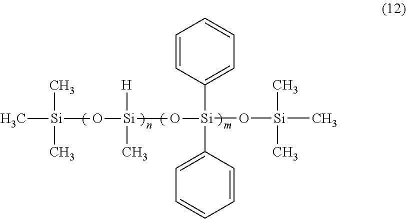

wherein an average of n is 28, an average of m is 42, and an amount of the aromatic groups is 58%.

### Examples 2 to 8

The procedures in Example 1 were repeated, except that the amounts of the components were changed as described in Table 1.

### Comparative Example 1

The procedures in Example 1 were repeated, except that 1,3,5-triallylisocyanurate was used in an amount of 23.5 g, the compound represented by the formula (11) was used in an amount of 76.5 g and the compound represented by the formula (12) was not used.

### Comparative Example 2

The procedures in Example 1 were repeated, except that 1,3,5-triallylisocyanurate was used in an amount of 17 g, the compound represented by the formula (12) was used in an amount of 83 g and the compound represented by the formula (11) was not used.

The curable compositions prepared in Examples 1 to 8 and Comparative Examples 1 and 2 were evaluated according to the following manners.

### Refractive Index of the Curable Compositions

A refractive index of the curable composition was determined according to the Japanese Industrial Standards (JIS) K 0062. The apparatus used was a digital refractometer, RX-9000α, ex Atago Co., Ltd. The results are as shown in Table 1.

### Surface Tackiness and Water Vapor Permeability of Cured Products

The curable composition was poured into a Teflon (registered trade mark) -coated mold having a length of 12 cm, a width of 12 cm, and a thickness of 1 mm and, then, the composition was heated at 60 degrees C. for one hour, subsequently at 100 degrees C. for one hour and, then, at 150 degrees C. for four hours to cure, yielding a sheet-shape product. A surface tackiness of the sheet-shape product was evaluated with a finger. A water vapor permeability of the sheet-shape product was determined in a Lyssy method with L80-5000, ex Systech Instruments Ltd. The results are as shown in Table 1.

### Hardness of Cured Products

A hardness with durometer type D of the cured product was determined according to JIS K 6253-3. The results are as shown in Table 1.

### Thermal Cycle Test

The curable composition was dispensed on a Tiger3528 package, ex Shin-Etsu Chemical Co., Ltd., and heated at 60 degrees C. for one hour, subsequently at 100 degrees C. for one hour and, then, at 150 degrees C. for four hours to cure, yielding a sample package encapsulated with the cured product. The test sample was subjected to a thermal cycle test (TCT) with 200 thermal cycles of −40 to 125 degrees C. When the cured product had cracks, it was evaluated as NG. When the test package had no crack, it was evaluated as DK. The results are as shown in Table 1.

### Transmittance of Cured Products

An arc-shaped Teflon (registered trade mark) spacer having a thickness of 1 mm was sandwiched between two glass slides having a dimension of 50 mm×20 mm×1 mm and tightly held, into which the curable composition was poured and heated at 60 degrees C. for one hour, subsequently at 100 degrees C. for one hour and, then, at 150 degrees C. for four hours to cure, yielding a sample for determination of a transmittance. A transmittance at 450 nm of the sample was determined with a spectrophotometer, U-4100, ex Hitachi High-Technologies Corporation.

TABLE 1

| | | Ex. 1 | Ex. 2 | Ex. 3 | Ex. 4 | Ex. 5 | Ex. 6 | Ex. 7 | Ex. 8 | Com. Ex. 1 | Com. Ex. 2 |
|---|---|---|---|---|---|---|---|---|---|---|---|
| (A) | TAIC | 21.5 | 22.9 | 19.3 | 20 | 36.5 | 8.3 | 21.5 | 21.5 | 23.5 | 17 |
| (B) | (B-1) Compound having —SiH groups at | 52.4 | 69.4 | 26.9 | 8 | 50.8 | 18.4 | 52.4 | 52.4 | 76.5 | — |
| | the both terminals, represented by the | | | | | | | | | | |
| | formula (11) | | | | | | | | | | |
| | (B-2) Compound having —SiH groups on | 26.2 | 7.7 | 53.8 | 72 | 12.7 | 73.4 | 26.2 | 26.2 | — | 83 |
| | a main chain, represented by the | | | | | | | | | | |
| | formula (12) | | | | | | | | | | |
| | Mass ratio of component (B-1) to | 2 | 9 | 0.5 | 0.11 | 4 | 0.2 | 2 | 2 | — | — |
| | component (B-2) | | | | | | | | | | |
| | Ratio of the number of —SiH groups to | 1.2 | 1.2 | 1.2 | 1.2 | 0.6 | 3.0 | 1.2 | 1.2 | 1.2 | 1.2 |
| | the number of vinyl groups | | | | | | | | | | |
| (C) | Catalyst, as an amount of platinum, ppm | 5 | 5 | 5 | 5 | 5 | 5 | 0.5 | 50 | 5 | 5 |
| Evaluation | Refractive index of the composition, n_{D}²⁵ | 1.54 | 1.53 | 1.54 | 1.55 | 1.53 | 1.55 | 1.54 | 1.54 | 1.53 | 1.55 |
| | Transmittance at 450 nm of the cured | 99.3 | 99.4 | 99.2 | 99.3 | 99.2 | 99.3 | 99.3 | 99.3 | 99.3 | 99.3 |
| | product having a thickness of 1 mm | | | | | | | | | | |
| | Hardness: Type D | 73 | 52 | 78 | 80 | 50 | 60 | 68 | 75 | 25 | 86 |
| | Water vapor permeability, g/m² · day | 4 | 8 | 3.5 | 3 | 8 | 6 | 4.5 | 4 | 16 | 3 |
| | Surface tackiness | None | None | None | None | None | None | None | None | Tacky | None |
| | TCT with 200 thermal cycles of −40 | OK | OK | OK | OK | OK | OK | OK | OK | OK | NG |
| | to 125 degrees C. | | | | | | | | | | |

### Examples 9 and 10 and Comparative Examples 3 and 4

The procedures in Example 1 were repeated, except that a compound represented by the following formula (13), ex Shin-Etsu Chemical Co., Ltd., was used instead of the compound represented by the formula (11), and a compound represented by the following formula (14), ex Shin-Etsu Chemical Co., Ltd., was used instead of the compound represented by the formula (12). The amounts of the components were as shown in the following Table 2. The curable compositions were evaluated in the same manners as in Example 1. The results are as shown in. Table 2.

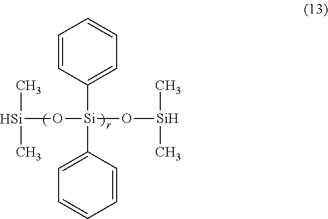

wherein r is 3 to 10, an average of r is 6 and an amount of the aromatic groups is 67%.

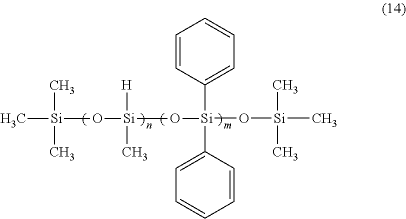

wherein an average of n is 37, an average of m is 110, and an amount of the aromatic groups is 73%.

TABLE 2

| | | Ex. 9 | Ex. 10 | Ex. 11 | Com. Ex. 4 |
|---|---|---|---|---|---|
| (A) | TAIC | 10.4 | 9.9 | 10.6 | 9.7 |
| (B) | (B-1) Compound having —SiH groups at | 71.6 | 18 | 89.4 | — |
| | the both terminals, represented by the | | | | |
| | formula (13) | | | | |
| | (B-2) Compound having —SiH groups on | 17.9 | 72.1 | — | 90.4 |
| | a main chain, represented by the | | | | |
| | formula (14) | | | | |
| | Mass ratio of component (B-1) to | 4 | 0.25 | — | — |
| | component (B-2) | | | | |
| | Ratio of the number of —SiH groups to | 1.2 | 1.2 | 1.2 | 1.2 |
| | the number of vinyl groups | | | | |
| (C) | Catalyst, as an amount of platinum, ppm | 5 | 5 | 5 | 5 |
| Evaluation | Refractive index of the composition, | 1.58 | 1.58 | 1.58 | 1.58 |
| | n_{D}²⁵ | | | | |
| | Transmittance at 450 nm of the cured | 98.9 | 99 | 98.9 | 98.8 |
| | product having a thickness of 1 mm | | | | |
| | Hardness: Type D | 58 | 84 | 37 | 88 |
| | Water vapor permeability, | 7 | 3 | 15 | 3 |
| | g/m² · day | | | | |
| | Surface tackiness | None | None | Tacky | None |
| | TCT with 200 thermal cycles of | OK | OK | OK | NG |
| | −40 to 125 degrees C. | | | | |

### Examples 11 and 12 and Comparative Examples 5 and 6

The procedures in Example 1 were repeated, except that a compound represented by the following formula (15), ex Shin-Etsu Chemical Co., Ltd., was used instead of the compound represented by the formula (11), and a compound represented by the following formula (16), ex Shin-Etsu Chemical Co., Ltd., was used instead of the compound represented by the formula (12). The amounts of the components were as shown in the following Table 3. The curable compositions were evaluated in the same manners as in Example 1. The results are as shown in Table 3.

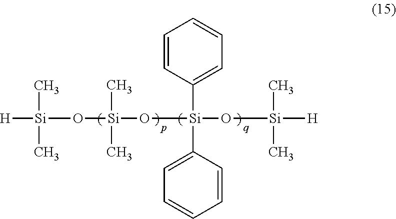

wherein an average of p is 25, an average of q is 3, and an amount of the aromatic groups is 10%.

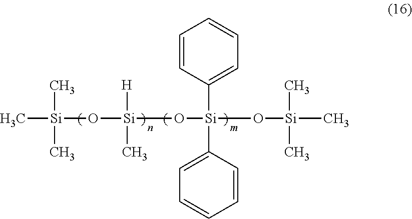

wherein an average of n is 90, an average of m is 10, and an amount of the aromatic groups is 10%.

TABLE 3

| | | Ex. 11 | Ex. 12 | Com. Ex. 5 | Com. Ex. 6 |
|---|---|---|---|---|---|
| (A) | TAIC | 17.5 | 40.6 | 5.2 | 45.7 |
| (B) | (B-1) Compound having —SiH groups at the | 66 | 11.9 | 94.8 | — |
| | both terminals, represented by the formula | | | | |
| | (15) | | | | |
| | (B-2) Compound having —SiH groups on a | 18.5 | 47.5 | — | 54.3 |
| | main chain, represented by the formula (16) | | | | |
| | Mass ratio of component (B-1) to component | 4 | 0.25 | — | — |
| | (B-2) | | | | |
| | Ratio of the number of —SiH groups to the | 1.18 | 1.18 | 1.18 | 1.18 |
| | number of vinyl groups | | | | |
| (C) | Catalyst, as an amount of platinum, ppm | 5 | 5 | 5 | 5 |
| Evaluation | Refractive index of the composition, n_{D}²⁵ | 1.46 | 1.48 | 1.46 | 1.48 |
| | Transmittance at 450 nm of the cured product | 99.5 | 99.4 | 99.3 | 99.3 |
| | having a thickness of 1 mm | | | | |
| | Hardness: Type D | 36 | 76 | 5 | 80 |
| | Water vapor permeability, g/m² · day | 15 | 9 | 56 | 8 |
| | Surface tackiness | None | None | Tacky | None |
| | TCT with 200 thermal cycles of −40 to 125 degrees C. | OK | OK | OK | NG |

### Examples 13 and 14 and Comparative Example 7

The procedures in Example 1 were repeated, except that a compound represented by the following formula (17), ex Shin-Etsu Chemical Co., Ltd., was used instead of the compound represented by the formula (11), and a compound represented by the following formula (16), ex Shin-Etsu Chemical Co., Ltd., was used instead of the compound represented by the formula (12). The amounts of the components were as shown in the following Table 4. The curable compositions were evaluated in the same manners as in Example 1. The results are as shown in Table 4.

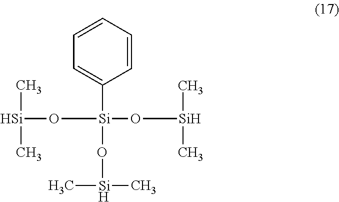

wherein an amount of the aromatic group is 10%.

TABLE 4

| | | Ex. 13 | Ex. 14 | Com. Ex. 7 |
|---|---|---|---|---|
| (A) | TAIC | 40 | 44 | 38.6 |
| (B) | (B-1) Compound having —SiH groups at the both terminals, | 48 | 11.2 | 61.4 |
| | represented by the formula (17) | | | |
| | (B-2) Compound having —SiH groups on a main chain, | 12 | 44.8 | — |
| | represented by the formula (16) | | | |
| | Mass ratio of component (B-1) to component (B-2) | 4 | 0.25 | — |
| | Ratio of the number of —SiH groups to the number of vinyl | 1.20 | 1.2 | 1.2 |
| | groups | | | |
| (C) | Catalyst, as an amount of platinum, ppm | 5 | 5 | 5 |
| Evaluation | Refractive index of the composition, n_{D}²⁵ | 1.48 | 1.48 | 1.48 |
| | Transmittance at 450 nm of the cured product having a | 99.3 | 99.4 | 99.4 |
| | thickness of 1 mm | | | |
| | Hardness: Type D | 55 | 78 | 46 |
| | Water vapor permeability, g/m² · day | 12.5 | 9 | 14 |
| | Surface tackiness | None | None | Tacky |
| | TCT with 200 thermal cycles of −40 to 125 degrees C. | OK | OK | OK |

### Example 15 and Comparative Examples 8 and 9

The procedures in Example 1 were repeated, except that monomethyl diallyl isocyanurate represented by the following formula (18), MeDAIC, ex Shikoku Chemicals Corporation, was used instead of TAIC, and a compound represented by the following formula (19), ex Shin-Etsu Chemical Co., Ltd., was used instead of the compound represented by the formula (12). The amounts of the component were as shown in the following Table 5. The curable compositions were evaluated in the same manners as in Example 1. The results are as shown in Table 5.

### Example 16

The procedures in Example 1 were repeated, except that monomethyl diallyl isocyanurate represented by the following formula (18), MeDAIC, ex Shikoku Chemicals Corporation, was used in addition to TAIC, and a compound represented by the following formula (19), ex Shin-Etsu Chemical Co., Ltd., was used instead of the compound represented by the formula (12). The amounts of the components were as shown in the following Table 5. The curable composition was evaluated in the same manners as in Example 1. The results are as shown in Table 5.

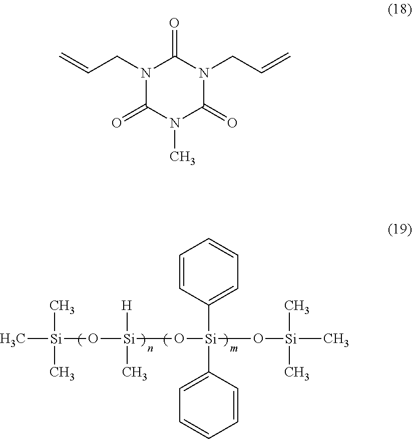

wherein an average of n is 37, an average of m is 110 and an amount of the aromatic groups is 73%.

TABLE 5

| | | Ex. 15 | Ex. 16 | Com. Ex. 8 | Com. Ex. 9 |
|---|---|---|---|---|---|
| (A) | TAIC | — | 12.9 | — | — |
| | MeDAIC | 28.9 | 12.9 | 29.3 | 28.3 |
| (B) | (B-1) Compound having —SiH groups at the both | 47.4 | 49.5 | 70.7 | — |
| | terminals, represented by the formula (11) | | | | |
| | (B-2) Compound having —SiH groups on a main chain, | 23.7 | 24.7 | — | 71.7 |
| | represented by the formula (19) | | | | |
| | Mass ratio of component (B-1) to component (B-2) | 2 | 2 | — | — |
| | Ratio of the number of —SiH groups to that of vinyl | 1.2 | 1.2 | 1.2 | 1.2 |
| | groups | | | | |
| (C) | Catalyst, as an amount of platinum, ppm | 5 | 5 | 5 | 5 |
| Evaluation | Refractive index of the composition, n_{D}²⁵ | 1.54 | 1.54 | 1.53 | 1.54 |
| | Transmittance at 450 nm of the cured product having | 99.1 | 99 | The | 98.9 |
| | a thickness of 1 mm | | | composition | |
| | Hardness: Type D | 63 | 68 | did not | 80 |
| | Water vapor permeability, g/m² · day | 5.5 | 4.5 | cure. | 3.5 |
| | Surface tackiness | None | None | | None |
| | TCT with 200 thermal cycles of −40 to 125 degrees C. | OK | OK | | NG |

As seen in the Tables 1 to 5, the present curable composition comprising component (B-1) in combination with component (B-2) provides a cured product having both of an excellent gas barrier property and excellent crack resistance under the thermal cycle conditions. In contrast, the compositions in Comparative Examples 1 to 9 which lack either component (B-1) or (B-2) do not provide a cured product having both of an excellent gas barrier property and excellent crack resistance.

### Comparative Example 10

The procedures in Example 1 were repeated, except that the amount of 1,3,5-triallylisocyanurate was changed to 31.8 g, and 45.5 g of a compound represented by the following formula (20), ex Shin-Etsu Chemical Co., Ltd., was used instead of the compound represented by the formula (11), and 22.8 g of a compound represented by the following formula (21), ex Shin-Etsu Chemical Co., Ltd., was used instead of the compound represented by the formula (12). 1,3,5-Triallylisocyanurate was not compatible with the compounds represented by the formulas (20) and (21) to cause a phase separation, so that a curable composition was not obtained.

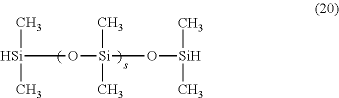

wherein an average of s is 10.

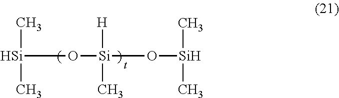

wherein an average of t is 38.

### Comparative Example 11

The procedures in Example 1 were repeated, except that the amount of 1,3,5-triallylisocyanurate was changed to 25.2 g, and 49.9 g of a compound represented by the following formula (22), ex Shin-Etsu Chemical Co., Ltd., was used instead of the compound represented by the formula (11), and 25.0 g of a compound represented by the following formula (23), ex Shin-Etsu Chemical Co., Ltd., was used instead of the compound represented by the formula (12).

1,3,5-Triallylisocyanurate was not compatible with the compounds represented by the formulas (22) and (23) to cause a phase separation, so that a curable composition was not obtained.

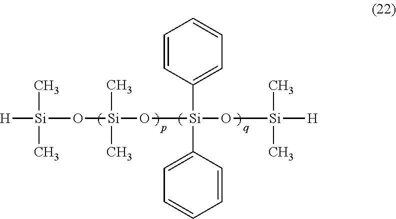

wherein an average of p is 55, an average of q is 3, and an amount of the aromatic groups is 5%.

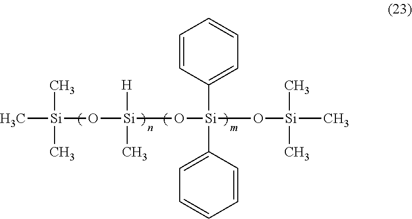

wherein an average of n is 74, an average of m is 4, and an amount of the aromatic groups is 5%.

As seen in Comparative Examples 10 and 11, when the organopolysiloxane does not have the specific amount of monovalent aromatic hydrocarbon group bonded to a silicon atom, the composition is not compatible with an isocyanurate and does not provide a transparent curable composition. In contrast, in the present composition, the organopolysiloxane is well compatible with the isocyanurate, so that the present composition provides a cured product having a higher transparency, in particular a higher optical transparency.

### INDUSTRIAL APPLICABILITY

The present composition provides a cured product having an excellent mechanical strength, an excellent gas barrier property such as low water vapor permeability, and excellent crack resistance. Additionally, the present curable composition has a high transparency in an uncured state, so that a cured product has a high optical transparency. Further, the present composition is prepared in a simple process and, therefore, the composition has an advantage of low costs. Accordingly, the present curable composition is useful as an encapsulating material for an optical semiconductor device, in particular a material for protecting LED chips and metal lines.

1. A curable composition comprising
(A) an isocyanurate represented by the following formula (1): 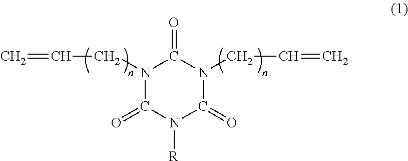
wherein n is, independently of each other, an integer of from 1 to 10, R is selected from the group consisting of monovalent hydrocarbon groups which have 1 to 12 carbon atoms and may have an aliphatic or aromatic unsaturated double bond, an epoxy group and a (meth)acryl group,
(B) a combination of the following components (B-1) and (B-2) in an amount such that a ratio of the number of —SiH groups in component (B) to a total number of the aliphatic unsaturated double bond in component (A) is 0.5 to 4:
(B-1) a non-cyclic organopolysiloxane which may have a branched structure, has hydrogen atoms each bonded to a silicon atom, i.e. —SiH group, at at least two terminals, and has monovalent aromatic hydrocarbon groups each bonded to a silicon atom in an amount of 10% or more, relative to a total number of substituents and hydrogen atoms each bonded to a silicon atom; and
(B-2) a non-cyclic organopolysiloxane which may have a branched structure, has at least two hydrogen atoms each bonded to a silicon atom in a main and/or branched chains, i.e. —SiH group, but no SiH group at any terminal, and has a monovalent aromatic hydrocarbon group bonded to a silicon atom in an amount of 10% or more, relative to a total number of substituents and hydrogen atoms each bonded to a silicon atom,
wherein an amount of component (B-2) is 1 to 99 mass %, relative to a total amount of components (B-1) and (B-2); and
(C) a hydrosilylation catalyst in a catalytic amount.

2. The curable composition according to claim 1, wherein component (B-1) is represented by the following formula (2): 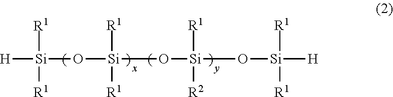
wherein R¹ is, independently of each other, a substituted or unsubstituted monovalent hydrocarbon group which has 1 to 12 carbon atoms and has no aliphatic unsaturated bond, R² is, independently of each other, selected from the aforementioned groups defined for R¹ or a group represented by the following formula (3): 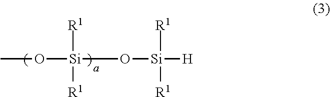
wherein 10% or more of a total number of the substituents and the hydrogen atoms each bonded to a silicon atom is a monovalent aromatic hydrocarbon group, the parenthesized siloxane units may form a block unit or bond randomly, x is an integer of from 0 to 100, y is an integer of from 0 to 100, a is an integer of from 0 to 100, and a total of x, y and a is 1 to 300.

3. The curable composition according to claim 1, wherein the component (B-2) is represented by the following formula (4): 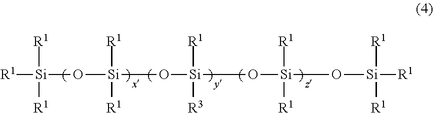
wherein R¹ is, independently of each other, a monovalent hydrocarbon group which has 1 to 12 carbon atoms and has no aliphatic unsaturated bond, R³ is a group represented by the following formula(5): 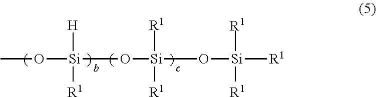
wherein 10% or more of a total number of the substituents and the hydrogen atoms each bonded to a silicon atom is a monovalent aromatic hydrocarbon group, the parenthesized siloxane units may form a block unit or bond randomly, x′ is an integer of from 0 to 300, y′ is an integer of from 0 to 300, and z′ is an integer of from 0 to 300, b is an integer of from 0 to 300, c is an integer of from 0 to 300, a total of x′, y′, z′, b and c is 2 to 500 and a total of z′ and b is 2 or more.

4. The curable composition according to claim 1, wherein the number of the monovalent aromatic hydrocarbon groups each bonded to a silicon atom in each organopolysiloxane is 10 to 80%, relative to a total number of the substituents and hydrogen atoms each bonded to a silicon atom.

5. An optical semiconductor device provided with a cured product obtained by curing the curable composition according to claim 1.

6. The curable composition according to claim 2, wherein the component (B-2) is represented by the following formula (4): 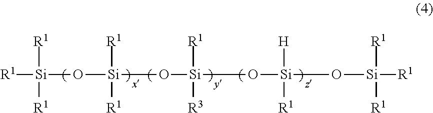
wherein R¹ is, independently of each other, a monovalent hydrocarbon group which has 1 to 12 carbon atoms and has no aliphatic unsaturated bond, R³ is a group represented by the following formula(5): 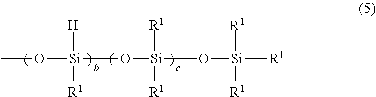
wherein 10% or more of a total number of the substituents and the hydrogen atoms each bonded to a silicon atom is a monovalent aromatic hydrocarbon group, the parenthesized siloxane units may form a block unit or bond randomly, x′ is an integer of from 0 to 300, y′ is an integer of from 0 to 300, and z′ is an integer of from 0 to 300, b is an integer of from 0 to 300, c is an integer of from 0 to 300, a total of x′, y′, z′, b and c is 2 to 500 and a total of z′ and b is 2 or more.

7. The curable composition according to claim 2, wherein the number of the monovalent aromatic hydrocarbon groups each bonded to a silicon atom in each organopolysiloxane is 10 to 80%, relative to a total number of the substituents and hydrogen atoms each bonded to a silicon atom.

8. The curable composition according to claim 3, wherein the number of the monovalent aromatic hydrocarbon groups each bonded to a silicon atom in each organopolysiloxane is 10 to 80%, relative to a total number of the substituents and hydrogen atoms each bonded to a silicon atom.

9. The curable composition according to claim 6, wherein the number of the monovalent aromatic hydrocarbon groups each bonded to a silicon atom in each organopolysiloxane is 10 to 80%, relative to a total number of the substituents and hydrogen atoms each bonded to a silicon atom.

10. An optical semiconductor device provided with a cured product obtained by curing the curable composition according to claim 2.

11. An optical semiconductor device provided with a cured product obtained by curing the curable composition according to claim 3.

12. An optical semiconductor device provided with a cured product obtained by curing the curable composition according to claim 6.

13. An optical semiconductor device provided with a cured product obtained by curing the curable composition according to claim 4.

14. An optical semiconductor device provided with a cured product obtained by curing the curable composition according to claim 7.

15. An optical semiconductor device provided with a cured product obtained by curing the curable composition according to claim 8.

16. An optical semiconductor device provided with a cured product obtained by curing the curable composition according to claim 9.
